(19) United States
(12) Patent Application Publication
(10) Pub. No.: US 2006/0193392 A1
(43) Pub. Date: Aug. 31, 2006

(54) Apparatus for and method of compensation for frequency offset and channel variation in MIMO-OFDM receiver

(75) Inventors: Jae-hwa Kim, Siheung-si (KR); Tae-kon Kim, Seongnam-si (KR); Jae-ho Chung, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/330,094

(22) Filed: Jan. 12, 2006

(30) Foreign Application Priority Data
Feb. 26, 2005 (KR) 10-2005-0016264

(51) Int. Cl. H04K 1/10; H04L 27/06; H03D 1/04

(52) U.S. Cl. 375/260; 375/343; 375/346

(57) ABSTRACT

An apparatus for compensating for a frequency offset and a channel variation, includes: a frequency offset compensation unit estimating the frequency offset of receptions signals received via reception ends based on a final metric value of the reception signals, and a compensator compensating for the frequency offset of the receptions signals based on the estimated frequency offset; Fast Fourier Transformers (FFTs) converting reception signals having the compensated frequency offset into frequency domain reception signals; and a frequency offset and channel variation compensation unit estimating channel coefficients of signals output from the FFTs by sub carriers, compensating for a residual frequency offset and a channel variation of the reception signals from the FFTs based on pilot signals and the estimated channel coefficients, and detecting signals transmitted from transmission ends based on the reception signals having the compensated residual frequency offset and channel variation and the estimated channel coefficients.

### BACKGROUND OF THE INVENTION

This application claims priority from Korean Patent Application No. 10-2005-0016264, filed on Feb. 26, 2005, in the Korean Intellectual Property Office, the disclosure of which is incorporated herein in its entirety by reference.

1. Field of the Invention

Apparatuses and methods consistent with the present invention relate to compensating for frequency offset and channel variation, and more particularly, to compensating for frequency offset and channel variation in a Multi-Input Multi-Output (MIMO)-Orthogonal Frequency Division Multiplex (OFDM) receiver.

2. Description of the Related Art

An OFDM receiver is generally used in a physical layer of a wireless local area network (LAN). The frequency of the OFDM receiver is not synchronized with the frequency of a transmission end due to distortion of a reception signal caused by multi-path fading and a difference between their respective local oscillating frequencies. Therefore, the OFDM receiver has a frequency offset compensation function so that the frequency of the reception signal does not exceed a frequency sync tolerance.

FIG. 1 is a block diagram of a conventional OFDM receiver having a frequency offset compensation function. Referring to FIG. 1, the conventional OFDM receiver comprises an RF down-converter 111 that converts a radio frequency (RF) signal received through an antenna 101 into a baseband signal, a local oscillator (LO) 112, an Analog-to-Digital Converter (ADC) 120 that converts an analog signal into a digital signal, a first frequency offset compensator 130 that compensates for a frequency offset of carriers that is output from the ADC 120, an Fast Fourier Transformer (FFT) 140 that converts a time domain signal into a frequency domain signal, a second frequency offset compensator 150 that compensates for a residual frequency offset of an output signal from the FFT 140, a demapper 160 that maps a restored Quadrature Amplitude Modulation (QAM) signal to a bit stream, and a Forward Error Correction (FEC) decoder 170 that decodes a coded bit stream.

When the RF down-converter 111 converts the RF signal received through the antenna 101 into the baseband signal, if the received RF signal is distorted due to a frequency difference between the LO 112 of a reception end and an LO (not shown) of a transmission end, the ADC 120 samples the distorted baseband signal and converts the sampled signal into a digital signal.

In order to obtain an undistorted reception signal from the distorted digital signal converted by the ADC 120, the first frequency offset compensator 130 delay-correlates a periodically repeated time domain sample using a delay correlator 131, estimates a frequency offset value by measuring a phase angle of a complex number value with regard to the delay-correlated samples using an arc tangent arithmetic unit 132, generates a complex metric function having a frequency with regard to the estimated frequency offset value using a Numeric Controlled Oscillator (NCO) 133, and multiplies a conjugate value of the complex metric function by the time domain reception signal output from the ADC using a multiplier 134 to compensate for the frequency offset.

The reception signal whose frequency offset is compensated is converted into a frequency domain signal using the FFT 140. However, the frequency domain signal produced by the FFT 140 may be distorted due to multi-path fading when a transmission signal passes through a channel.

In order to compensate for such a distortion of the reception signal due to multi-path fading, the second frequency offset compensator 150 compensates for the residual frequency offset of the output signal from the FFT 140.

To this end, the second frequency offset compensator 150 estimates channel coefficients according to each of sub carrier locations using a channel estimator 151 and stores the estimated channel coefficients in a memory 152. The second frequency offset compensator 150 divides data symbols after the preamble of the reception signal by the estimated channel coefficients stored in the memory 152 using a divider 153 and restores an original transmission signal. Such a restoration process of the second frequency offset compensator 150 is referred to as an equalization process of the reception signal.

If the second frequency offset compensator 150 is operated, ideally, since only effects of additional noise remain in the restored transmission signal, it is not necessary to perform further compensation for signal distortion. However, values estimated in the preamble section at an initial packet stage slowly change due to an estimation error of the frequency offset and minute variations in the characteristics of the channel.

To compensate for such variations, the transmission end transmits a previously known pilot signal to several sub carrier locations in the data symbol and the reception end estimates a variation in the reception signal using the pilot signal and compensates for redundant distortions.

Therefore, the second frequency offset compensator 150 estimates the phase and size varied on the average in a data symbol by calculating the average of pilot signals included in the restored transmission signal using a switch 154 and an average detector 155, and obtains a signal whose residual frequency offset is compensated after the FFT 140 by dividing data sub carriers in the data symbol by the average using the divider 156.

The demapper 160 converts signals whose residual frequency offset is compensated into a bit stream. The FEC decoder 170 performs error correction decoding using the bit stream from the demapper 160 and obtains final bit information.

However, the frequency offset compensation of the conventional OFDM receiver can be applied to a Single-Input Single-Output (SISO) communication system comprising a single transmission antenna and a single reception antenna but cannot be applied to an MIMO communication system that transmits spatial-multiplexed multi-bit streams using a plurality of transmission antennas and receives them using a plurality of reception antennas.

A frequency unbalance between a plurality of transmission ends and a frequency unbalance between a plurality of reception ends must be considered in the MIMO communication system. However, since the conventional OFDM receiver considers for only a frequency offset between a single transmission end and a single reception end, it is difficult to apply the conventional OFDM receiver to the MIMO communication system.

### SUMMARY OF THE INVENTION

The present invention provides an apparatus for and a method of compensating for a frequency offset and a channel variation, which are suitable for an MIMO communication system, and an MIMO-OFDM receiver.

The present invention also provides an apparatus for and a method of accurately estimating and compensating for a frequency offset and a channel variation using a plurality of reception signals, and an MIMO-OFDM receiver.

According to an aspect of the present invention, there is provided an apparatus for compensating for a frequency offset between a plurality of reception signals, the apparatus comprising: a plurality of delay correlators detecting delay correlation values of the plurality of receptions signals; a final metric value detector detecting a final metric value based on the delay correlation values of the plurality of receptions signals; a frequency offset estimator estimating the frequency offset of the plurality of receptions signals based on the final metric value; and a compensator compensating for the frequency offset of the plurality of receptions signals based on the estimated frequency offset.

According to another aspect of the present invention, there is provided an apparatus for compensating for a frequency offset and a channel variation of a receiver having a plurality of reception ends that receives a transmission signal including pilot signals crossing each other transmitted from a plurality of transmission ends, the apparatus comprising: a plurality of channel estimators estimating channel coefficients of reception signals received from the plurality of reception ends by sub carriers; and a pre-compensator compensating for a residual frequency offset and a channel variation of the plurality of reception signals based on the estimated channel coefficients and the pilot signals.

According to still another aspect of the present invention, there is provided a receiver having a plurality of reception ends, the receiver comprising: a plurality of delay correlators detecting delay correlation values of a plurality of receptions signals transmitted from the plurality of reception ends; a final metric value detector detecting a final metric value based on the delay correlation values of the plurality of receptions signals; a frequency offset estimator estimating the frequency offset of the plurality of receptions signals based on the final metric value; and a compensator compensating for the frequency offset of the plurality of receptions signals based on the estimated frequency offset.

According to yet another aspect of the present invention, there is provided a receiver having a plurality of reception ends that receives a transmission signal including pilot signals crossing each other transmitted from a plurality of transmission ends, the receiver comprising: a plurality of channel estimators estimating channel coefficients of reception signals received from the plurality of reception ends by sub carriers; and a pre-compensator compensating for a residual frequency offset and a channel variation of the plurality of reception signals based on the estimated channel coefficients and the pilot signals.

According to still another aspect of the present invention, there is provided a receiver that receives a transmission signal including pilot signals crossing each other transmitted from a plurality of transmission ends in a plurality of reception ends, the receiver comprising: a frequency offset compensation unit estimating the frequency offset of a plurality of receptions signals received via the plurality of reception ends based on a final metric value of the plurality of reception signals, and a compensator compensating for the frequency offset of the plurality of receptions signals based on the estimated frequency offset; a plurality of FFTs converting reception signals having the compensated frequency offset into frequency domain reception signals; and a frequency offset and channel variation compensation unit estimating channel coefficients of signals output from the plurality of FFTs by sub carriers, compensating for a residual frequency offset and a channel variation of the reception signals from the plurality of FFTs based on the pilot signals and the estimated channel coefficients, and detecting signals transmitted from the plurality of transmission ends based on the reception signals having the compensated residual frequency offset and channel variation and the estimated channel coefficients.

According to further another aspect of the present invention, there is provided a method of compensating for a frequency offset of a plurality of reception signals, the method comprising: detecting delay correlation values of the plurality of receptions signals; detecting a final metric value based on the delay correlation values of the plurality of receptions signals; estimating the frequency offset of the plurality of receptions signals based on the final metric value; and compensating for the frequency offset of the plurality of receptions signals based on the estimated frequency offset.

According to a further another aspect of the present invention, there is provided a method of compensating for a frequency offset and a channel variation of a receiver that receives a transmission signal including pilot signals crossing each other transmitted from a plurality of transmission ends in a plurality of reception ends, the method comprising: estimating channel coefficients of reception signals received from the plurality of reception ends by sub carriers; and compensating for a residual frequency offset and a channel variation of the plurality of reception signals based on the estimated channel coefficients and the pilot signals.

According to a further another aspect of the present invention, there is provided a method of compensating for a frequency offset and a channel variation of a receiver having a plurality of reception ends that receives a transmission signal including pilot signals crossing each other transmitted from a plurality of transmission ends, the method comprising: detecting delay correlation values of the plurality of receptions signals; detecting a final metric value based on the delay correlation values of the plurality of receptions signals; estimating the frequency offset of the plurality of receptions signals based on the final metric value; compensating for the frequency offset of the plurality of receptions signals based on the estimated frequency offset; converting reception signals having the compensated frequency offset into frequency domain signals; estimating channel coefficients of the frequency domain signals by sub carriers; compensating for a residual frequency offset and a channel variation of the reception signals based on the pilot signals and the estimated channel coefficients; and detecting signals transmitted from the plurality of transmission ends based on the reception signals having the compensated residual frequency offset and the channel variation and the estimated channel coefficients.

### BRIEF DESCRIPTION OF THE DRAWINGS

The above and/or other aspects of the present invention will become more apparent by describing in detail exemplary embodiments thereof with reference to the attached drawings in which:

FIG. 1 is a block diagram of a conventional OFDM receiver having a frequency offset compensation function;

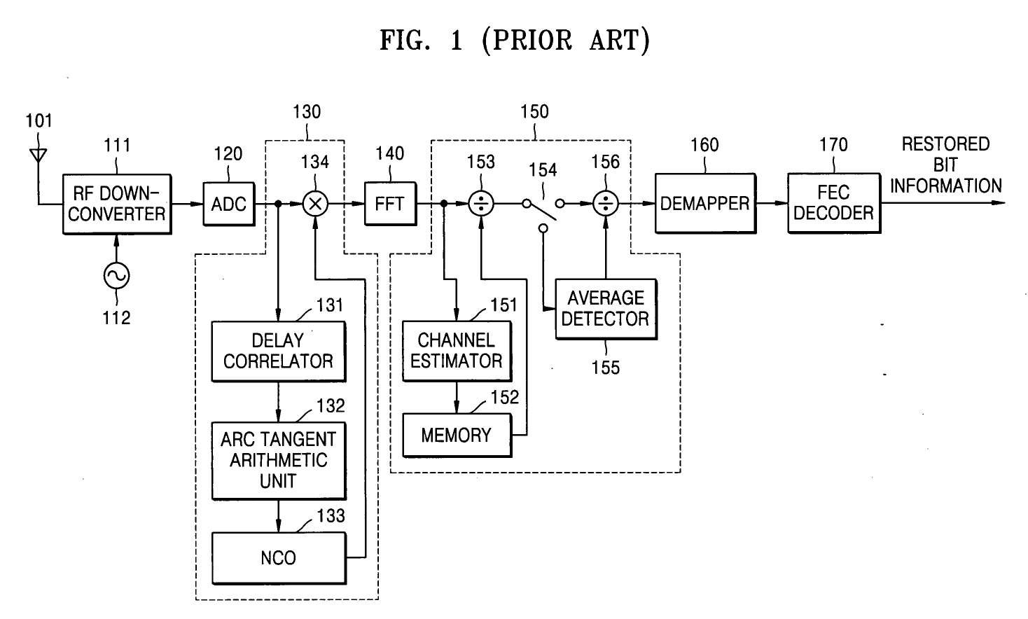

FIG. 2 is a block diagram of an MIMO-OFDM receiver having an apparatus for compensating for a frequency offset and a channel variation according to an exemplary embodiment of the present invention;

FIG. 3 exemplarily illustrates the transmission of pilot signals;

FIG. 4 illustrates a pre-compensator shown in FIG. 2 according to an exemplary embodiment of the present invention;

FIG. 5 illustrates a pre-compensator shown in FIG. 2 according to another exemplary embodiment of the present invention;

FIG. 6 illustrates a pre-compensator shown in FIG. 2 according to a still another exemplary embodiment of the present invention;

FIG. 7 illustrates a pre-compensator shown in FIG. 2 according to a yet another exemplary embodiment of the present invention; and

FIG. 8 is a flowchart of a method of compensating for a frequency offset and a channel variation according to an exemplary embodiment of the present invention.

### DETAILED DESCRIPTION OF EXEMPLARY EMBODIMENTS OF THE INVENTION

The present invention will now be described more fully with reference to the accompanying drawings, in which exemplary embodiments of the invention are shown.

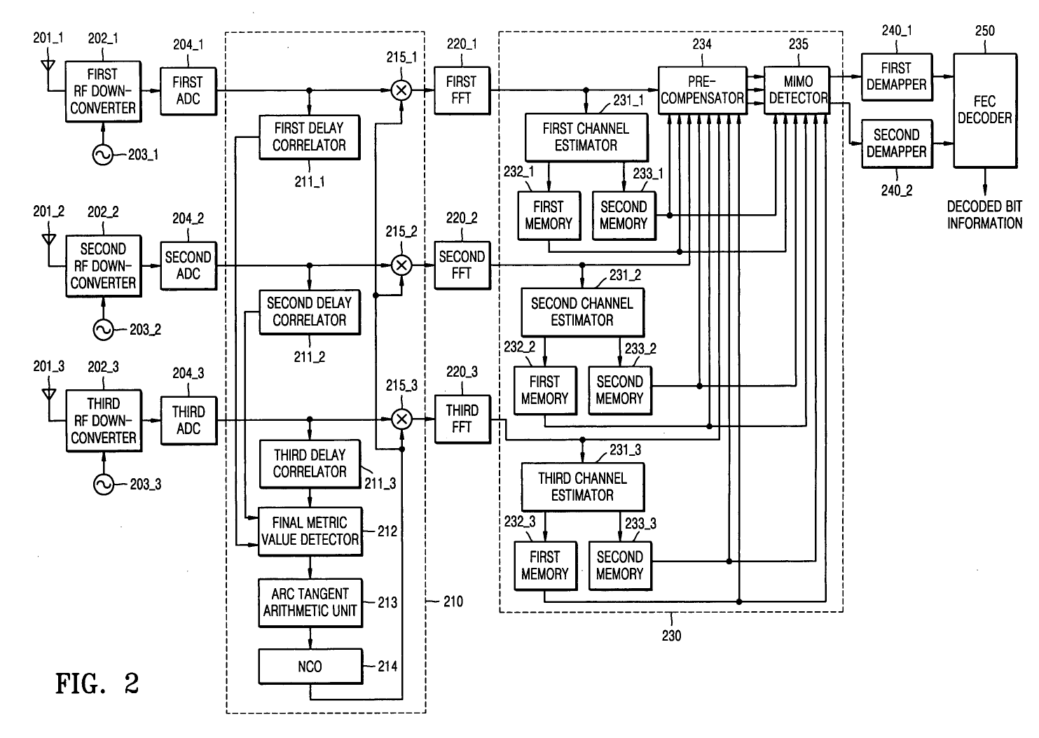

FIG. 2 is a block diagram of an MIMO-OFDM receiver having an apparatus for compensating for a frequency offset and a channel variation according to an exemplary embodiment of the present invention. The OFDM receiver includes three reception ends. Referring to FIG. 2, the OFDM receiver comprises first through third antennas 201_1 through 201_3, first through third RF down-converters 202_1 through 202_3, first through third LOs 203_1 through 203_3, first through third ADCs 204_1 through 204_3, a frequency offset compensation unit 210, first through third Fast Fourier Transformers (FFTs) 220_1 through 220_3, a residual frequency offset and channel variation compensation unit 230, first and second demappers 240_1 and 240_2, and an FEC decoder 250.

The frequency offset compensation unit 210 is referred to as a frequency offset compensation apparatus according to this exemplary embodiment of the present invention. The residual frequency offset and channel variation compensation unit 230 is referred to as a residual frequency offset and channel variation compensation apparatus according to this exemplary embodiment of the present invention.

The first through third RF down-converters 202_1 through 202_3 convert RF signals received from the first through third antennas 201_1 through 201_3, respectively, into baseband signals. The first LO 203_1 provides an LO frequency to the first RF down-converter 202_1, the second LO 203_2 provides the LO frequency to the second RF down-converter 202_2, and the third LO 203_3 provides the LO frequency to the third RF down-converter 202_3. The first through third LOs 203_1 through 203_3 may be configured as a single LO.

The first ADC 204_1 converts the baseband signal output from the first RF down-converter 202_1 into a digital signal. The second ADC 204_2 converts the baseband signal output from the second RF down-converter 202_2 into the digital signal. The third ADC 204_3 converts the baseband signal output from the third RF down-converter 202_3 into a digital signal.

The frequency offset compensation unit 210 compensates for frequency offsets of carriers of digital signals output from the first through third ADCs 204_1 through 204_3. The frequency offset compensation unit 210 comprises first through third delay correlators 211_1 through 211_3 corresponding to the first through third ADCs 204_1 through 204_3, a final metric value detector 212, an arc tangent arithmetic unit 213, an NCO 214, and first through third multipliers 215_1 through 215_3 corresponding to the first through third ADCs 204_1 through 204_3.

In the OFDM receiver, which is based on the IEEE 802.11a standards, since 10 patterns repeated every 16 samples are transmitted in a short preamble section, the first through third delay correlators 211_1 through 211_3 obtain complex delay correlation values rₙ(t) using a delay correlator having a delay of sixteen samples as follows:

$${r}_{n} ( t ) = \frac{1}{16} {\sum }_{k = 0}^{15} {y}_{n} ( t - k ) {y}_{n}^{*} ( t - k - 16 ) \qquad ( 1 )$$

wherein, yₙ(t) denotes a reception signal in the short preamble section of an n^{th} reception antenna, t denotes a time metric in the reception signal, k denotes a delay metric, and * denotes a conjugate value.

The final metric value detector 212 obtains a final metric value m(t) using an average of the delay correlation values rₙ(t) output from the first through third delay correlators 211_1 through 211_3 by which the effect of noise is reduced, as follows:

$$m ( t ) = \frac{1}{N} {\sum }_{n = 1}^{N} {r}_{n} ( t ) \qquad ( 2 )$$

The final metric value m(t) is used to estimate a frequency offset.

The final metric value detector 212 selects a delay correlation value of a reception signal having the greatest power among the input delay correlation values as a representative value.

The arc tangent arithmetic unit 213 calculates im(m(t_{d}))/re(m(t_{d})), a phase angle of the final metric value m(t). The numerator im(m(t_{d})) denotes an imaginary number of the final metric value m(t) at a signal detection point t_{d} and the denominator re(m(t_{d})) denotes a real number of the final metric value m(t) at a signal detection point t_{d}. The arc tangent arithmetic unit 213 multiplies the calculated phase angle by a sampling period Tₛ, divides the multiplied value by a repetition period value of 16, and estimates a frequency offset Δ\hat{f} as follows:

$$Δ \hat{f} = {tan}^{- 1} \{ \frac{im ( m ( {t}_{d} ) )}{re ( m ( {t}_{d} ) )} \} \frac{{T}_{s}}{2 π16} \qquad ( 3 )$$

The estimated frequency offset value is sampled at the signal detection point t_{d} and fixed as a frequency offset value of the whole packet. The arc tangent arithmetic unit 213 transmits the estimated frequency offset value to the NCO 214.

The NCO 214 generates a complex metric signal corresponding to a frequency of the estimated frequency offset value as follows:
exp(−2π·j≠Δ\hat{f}·n·Tₛ) (4)

The complex metric signal is provided to each of the first through third multipliers 215_1 through 215_3.

The first through third multipliers 215_1 through 215_3 multiply the respective time domain reception signals by the complex metric signal and compensate for frequency offsets of reception signals. The reception signals having the compensated frequency offsets output from the first through third multipliers 215_1 through 215_3 are transmitted to the first through third FFTs 220_1 through 220_3.

The first through third FFTs 220_1 through 220_3 convert the respective time domain reception signals into frequency domain reception signals. The frequency domain reception signals are transmitted to the residual frequency offset and channel variation compensation unit 230.

The residual frequency offset and channel variation compensation unit 230 compensates for a residual frequency offset and a channel variation of the frequency domain reception signals. The residual frequency offset and channel variation compensation unit 230 comprises first through third channel estimators 231_1 through 231_3, three first memories 232_1 through 232_3, three second memories 233_1 through 233_3, a pre-compensator 234, and an MIMO detector 235 as shown in FIG. 2.

The first through third channel estimators 231_1 through 231_3, estimate a channel coefficient of a transmission end in unit of sub carriers at a corresponding reception end using signals corresponding to long preamble symbols in the frequency domain reception signal. At this time, orthogonality between long preambles transmitted from each transmission antenna must be maintained in order to obtain the channel number of paths between every transmission antenna and reception antenna. To this end, every transmission end alternately transmits long preambles while one transmission end transmits a long preamble to a section and the other transmission ends do not transmit a signal to the section.

Each of the first through third channel estimators 231_1 through 231_3 estimates channel coefficients of two transmission ends in unit of sub carriers. Therefore, the estimated channel coefficient of one transmission end is stored in the corresponding first memory 232_1 through 232_3 and the estimated channel coefficient of another transmission end is stored in the corresponding second memory 233_1 through 233_3. If the number of transmission ends is M, the first through third channel estimators 231_1 through 231_3 estimate M channel coefficients in unit of sub carriers and M memories substituted for the first memory 232_1 through 232_3 and the second memory 233_1 through 233_3 to store the estimated M channel coefficients.

The channel coefficients stored in the first memory 232_1 through 232_3 and the second memory 233_1 through 233_3 are read by the MIMO detector 235 in the data symbol section.

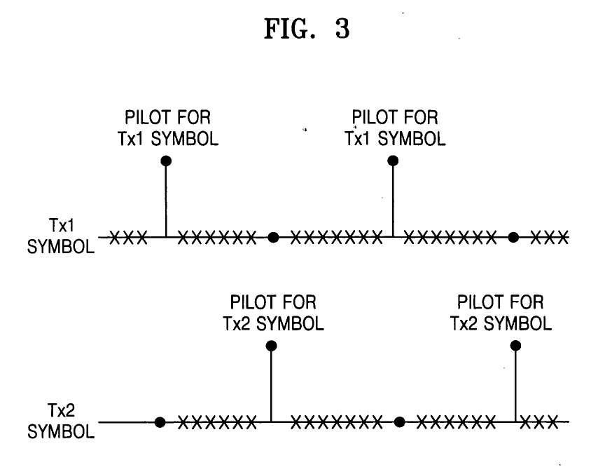

The pre-compensator 234 compensates for a residual frequency offset and a channel variation of the frequency domain reception signals using pilot signals and the channel coefficients stored in the first memory 232_1 through 232_3 and the second memory 233_1 through 233_3. The present invention supposes each transmission end to transmit by crossing pilot signals as shown in FIG. 3, which illustrates an example of the transmitting pilot signals. Referring to FIG. 3, four pilot signals are transmitted through two transmission antennas based on the IEEE 802.11a standards.

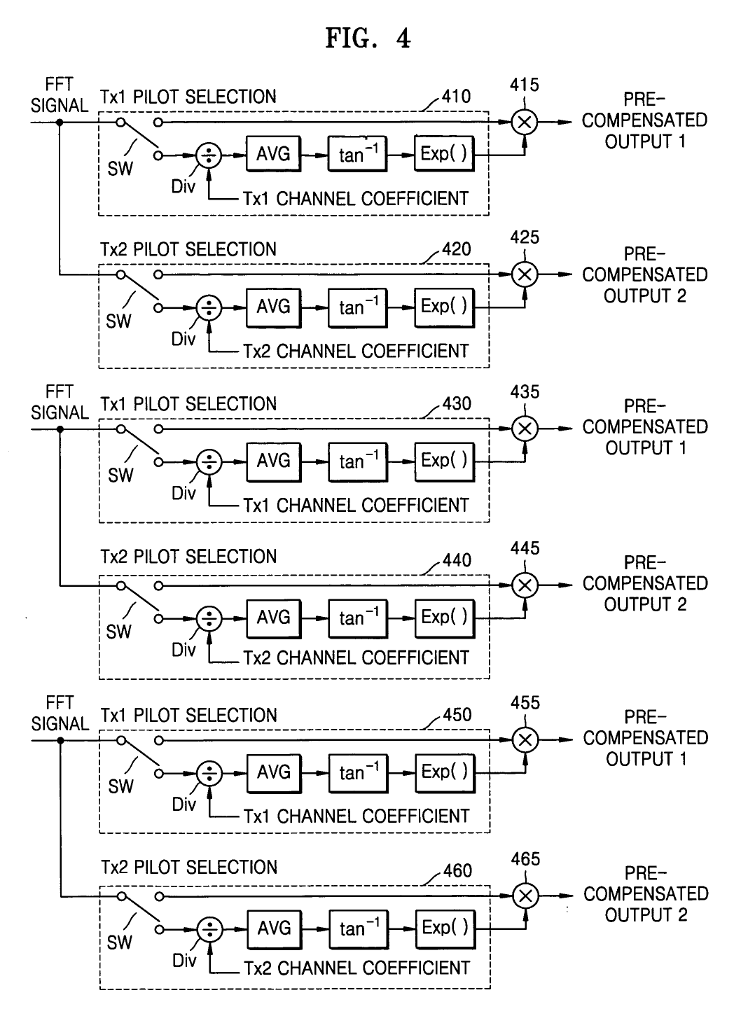

FIG. 4 illustrates the pre-compensator 234 shown in FIG. 2 according to an exemplary embodiment of the present invention. Referring to FIG. 4, when two transmission ends and three reception ends have a different frequency offset, the pre-compensator 234 includes channel coefficient variation rate detectors 410, 420, 430, 440, 450, and 460 to compensate for a residual frequency offset and a channel variation of the frequency domain reception signals.

The channel coefficient variation rate detectors 410, 4210, 430, 440, 450, and 460 comprise switches SW that select each corresponding pilot signal, dividers Div that divide pilot signals selected by the switches SW by a channel coefficient of a sub carrier, average detectors AVG that detect an average of current values and previous values output from the dividers DIV, arithmetic units tan⁻¹ that perform arc tangent arithmetic on the average detected by the average detectors AVG, and complex number metric value generators Exp( ) that generate a complex number metric value of the value output from the arithmetic units tan⁻¹. The complex number metric value corresponds to the channel coefficient variation rate.

An absolute value of the channel coefficient variation rate indicates a gain change of a channel and RF down-converter and a phase angle of the channel coefficient variation rate indicates a residual frequency offset. The channel coefficient variation rate is 1.0 when there is no channel variation. The average detectors AVG obtain an average of the channel coefficient variation rate when a plurality of pilot signals are transmitted in a transmission end, thereby accurately estimating a channel coefficient variation.

The pre-compensator 234 comprising multipliers 415, 425, 435, 445, 455, and 465 with regard to two transmission ends by each reception end multiplies the frequency domain reception signals by the channel coefficient variation rate detected from the corresponding channel coefficient variation rate detectors 410, 420, 430, 440, 450, and 460 using multipliers 415, 425, 435, 445, 455, and 465, and compensates for a residual frequency offset and a channel variation of the frequency domain reception signals. The reception signals having the compensated residual frequency offset and channel variation are pre-compensated outputs, which are transmitted to the MIMO detector 235.

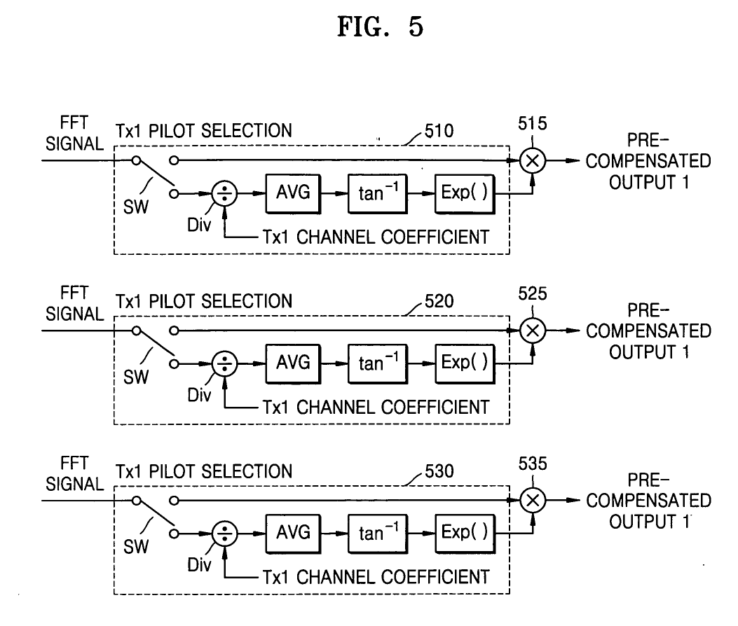

FIG. 5 illustrates the pre-compensator 234 shown in FIG. 2 according to another exemplary embodiment of the present invention. Referring to FIG. 4, each transmission end has the same frequency offset regardless of the number of transmission ends and three reception ends have a different frequency offset. Therefore, a parameter δω_{TX} indicating an unbalance between transmission ends has a value similar to 0. In this case, the pre-compensator 234 includes channel coefficient variation rate detectors 510, 520, and 530 and multipliers 515, 525, and 535 every reception end.

The channel coefficient variation rate detectors 510, 520, and 530 are identical to the channel coefficient variation rate detectors 410, 420, 430, 440, 450, and 460 shown in FIG. 4. The channel coefficient variation rate detectors 510, 520, and 530 use a channel coefficient stored in first and second memory corresponding to a reception end among first and second memory corresponding to each reception ends. The multipliers 515, 525, and 535 multiply channel coefficient variation rates provided by the channel coefficient variation rate detectors 510, 520, and 530 by reception signals transmitted through the corresponding reception ends and compensate for the residual frequency offset and the channel variation of the frequency domain reception signals. The reception signals having the compensated residual frequency offset and the channel variation are transmitted to the MIMO detector 235.

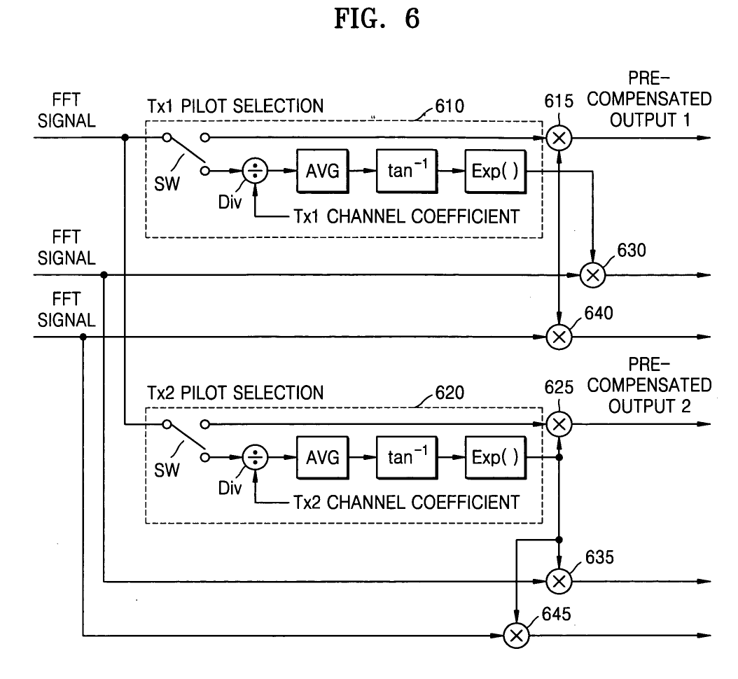

FIG. 6 illustrates the pre-compensator 234 shown in FIG. 2 according to still another exemplary embodiment of the present invention. Referring to FIG. 6, two transmission ends have a different frequency offset and three reception ends have the same frequency offset. Therefore, the parameter δω_{RX} indicating the unbalance between transmission ends has a value similar to 0.

In a reception end among the three reception ends, the pre-compensator 234 includes channel coefficient variation rate detectors 610 and 620 and multipliers 615 and 625 corresponding to the two transmission ends and multipliers 630, 635, 640, and 645 corresponding to the two transmission ends in the other two reception ends.

The multipliers 630, 635, 640, and 645 have channel coefficient variation rates output from the channel coefficient variation rate detectors 610 and 620 corresponding to the two transmission ends as input signals. That is, the multiplier 630 multiplies a channel coefficient variation rate output from the channel coefficient variation rate detector 610 by the frequency domain reception signal. The multiplier 635 multiplies a channel coefficient variation rate output from the channel coefficient variation rate detector 620 by the frequency domain reception signal. The multiplier 640 multiplies a channel coefficient variation rate output from the channel coefficient variation rate detector 610 by the frequency domain reception signal. The multiplier 645 multiplies a channel coefficient variation rate output from the channel coefficient variation rate detector 620 by the frequency domain reception signal.

The channel coefficient variation rate detectors 610 and 620 are identical to the channel coefficient variation rate detectors shown in FIGS. 4 and 5.

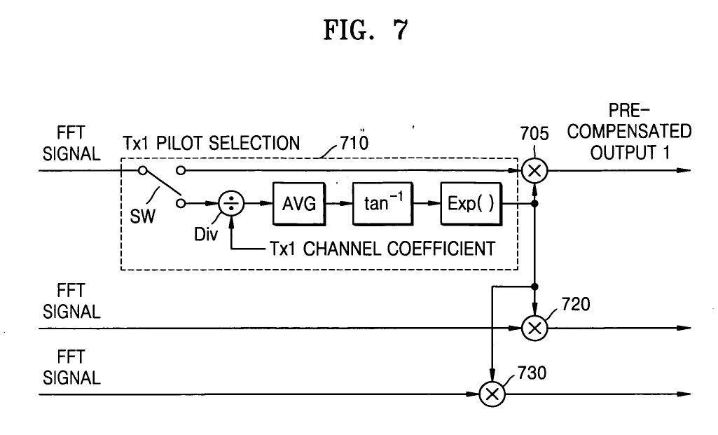

FIG. 7 illustrates the pre-compensator 234 shown in FIG. 2 according to yet another exemplary embodiment of the present invention. Referring to FIG. 7, regardless of the number of transmission ends, each transmission end has the same frequency offset as that of three reception ends. Therefore, the parameter δωTX and a parameter δω_{RX} have a value similar to 0.

The pre-compensator 234 shown in FIG. 7 includes a channel coefficient variation rate detector 710 and a multiplier 715 in one reception end among the three reception ends and multipliers 720 and 730 in the other two reception ends. The multipliers 720 and 730 multiply a channel coefficient variation rate provided by the channel coefficient variation rate detectors 710 by the frequency domain reception signal and output reception signals having the compensated residual frequency offset and the channel variation. The output reception signals are transmitted to the MIMO detector 235.

The channel coefficient variation rate detectors 710 use a channel coefficient stored in the first memory 232_1 or the second memory 233_1.

The MIMO detector 235 detects transmission signals in each reception signal transmitted from the pre-compensator 234 using channel coefficients stored in the memory 232_1 through 232_3, 233_1 through 233_3 corresponding to each reception end. Each reception signal is a signal having the compensated residual frequency offset and the channel variation.

The MIMO detector 235 uses one of Bell Labs Layered Space-Time (BLAST), Zero Forcing (ZF), Minimum Mean Squared Error (MMSE) linear equalization, and Maximum Likelihood (ML). In particular, the MIMO detector 235 detects transmission signals using linear arithmetic such as ZF and MMSE linear equalization.

When a transceiver has no frequency offset and the MIMO detector 235 uses ZF, the MIMO detector 235 detects a vector x of a transmission signal using a matrix H based on channel coefficients of each sub carrier read from the first and second memory 232_1 through 232_3, 233_1 through 233_3 corresponding to each reception end and a reception signal vector y of each reception end output from the pre-compensator 234 as follows:
\hat{x}=(H*H)⁻¹H*y (5)

Typically, in a case of two transmission ends and three reception signals, Equation 5 is modified as follows:

$$H = [ \begin{matrix}A & D \\ B & E \\ C & F\end{matrix} ] , \\ \begin{matrix}{H}^{*} H = [ \begin{matrix}{\vert A \vert}^{2} + {\vert B \vert}^{2} + {\vert C \vert}^{2} & {A}^{*} D + {B}^{*} E + {C}^{*} F \\ {D}^{*} A + {E}^{*} B + {F}^{*} C & {\vert D \vert}^{2} + {\vert E \vert}^{2} + {\vert F \vert}^{2}\end{matrix} ] \\ [ \begin{matrix}{σ}_{1}^{2} & {ρ}_{12} \\ {ρ}_{12}^{*} & {σ}_{2}^{2}\end{matrix} ]\end{matrix} \\ {( {H}^{*} H )}^{- 1} = \frac{1}{{σ}_{1}^{2} {σ}_{2}^{2} - {\vert {ρ}_{12} \vert}^{2}} [ \begin{matrix}{σ}_{2}^{2} & - {ρ}_{12} \\ - {ρ}_{12}^{*} & {σ}_{1}^{2}\end{matrix} ] \\ {H}^{*} y = [ \begin{matrix}{A}^{*} {y}_{1} + {B}^{*} {y}_{2} + {C}^{*} {y}_{3} \\ {D}^{*} {y}_{1} + {E}^{*} {y}_{2} + {F}^{*} {y}_{3}\end{matrix} ] \qquad ( 6 )$$

wherein, σ₁² and σ₂² denote channel coefficient power of the first and second transmission ends, respectively, and ρ₁₂ denotes a cross correlation value of a channel coefficient of the first and second transmission end.

When the channel varies, the channel coefficient matrix H of each sub carrier is defined as a varied channel coefficient matrix \tilde{H} which is obtained by multiplying each channel coefficient variation rate μ and channel coefficients as follows:

$$\tilde{H} = [ \begin{matrix}\tilde{A} & \tilde{D} \\ \tilde{B} & \tilde{E} \\ \tilde{C} & \tilde{F}\end{matrix} ] = [ \begin{matrix}{μ}_{A} \cdot A & {μ}_{D} \cdot D \\ {μ}_{B} \cdot B & {μ}_{E} \cdot E \\ {μ}_{C} \cdot C & {μ}_{F} \cdot F\end{matrix} ] \qquad ( 7 )$$

When one data symbol has no gain variation and has a residual frequency offset, each channel variation rate μ is expressed as a complex metric function. If a phase difference corresponding to a residual channel frequency offset is Δω, the varied channel coefficient matrix \tilde{H} is as follows:

$$\tilde{H} = [ \begin{matrix}exp ( j \cdot Δ {ω}_{A} ) \cdot A & exp ( j \cdot Δ {ω}_{D} ) \cdot D \\ exp ( j \cdot Δ {ω}_{B} ) \cdot B & exp ( j \cdot Δ {ω}_{E} ) \cdot E \\ exp ( j \cdot Δ {ω}_{C} ) \cdot C & exp ( j \cdot Δ {ω}_{F} ) \cdot F\end{matrix} ] \qquad ( 8 )$$

As shown above, the channel coefficient varied by the residual frequency offset is obtained by multiplying the channel coefficient H obtained in the long preamble section and each residual channel frequency offset Δω. In this case, the MIMO detector 235 must detect the MIMO using the varied channel coefficient matrix H instead of the channel coefficient H. To this end, Equation 6 based on the varied channel coefficient matrix \tilde{H} is modified to design the MIMO detector 235 that separates reception signals as follows:

$$\begin{matrix}{( {\tilde{H}}^{*} \tilde{H} )}^{- 1} = \frac{1}{{σ}_{1}^{2} {σ}_{2}^{2} - {\vert {ρ}_{12} \vert}^{2}} \\ [ \begin{matrix}{σ}_{2}^{2} & - exp ( - j \cdot {δω}_{Γ X} ) {ρ}_{12} \\ - exp ( j \cdot {δω}_{Γ X} ) {ρ}_{12}^{*} & {σ}_{1}^{2}\end{matrix} ]\end{matrix} \\ {\tilde{H}}^{*} y = [ \begin{matrix}\begin{matrix}exp ( - j \cdot Δ {ω}_{A} ) \cdot {A}^{*} \cdot {y}_{1} + exp ( - j \cdot {Δω}_{B} ) \cdot {B}^{*} \cdot {y}_{2} + \\ exp ( - j \cdot {Δω}_{C} ) \cdot {C}^{*} \cdot {y}_{3}\end{matrix} \\ \begin{matrix}exp ( - j \cdot {Δω}_{D} ) \cdot {D}^{*} \cdot {y}_{1} + exp ( - j \cdot {Δω}_{E} ) \cdot {E}^{*} \cdot {y}_{2} + \\ exp ( - j \cdot {Δω}_{F} ) \cdot {F}^{*} \cdot {y}_{3}\end{matrix}\end{matrix} ] \qquad ( 9 )$$

When the matrix of Equation 9 is applied to FIG. 4, exp(−j·Δω_{A})·y₁ is a value having the compensated residual frequency offset and channel variation provided by the multiplier 415, exp(−j·Δω_{B})·y₂ is a value having the compensated residual frequency offset and channel variation provided by the multiplier 435, exp(−j·Δω_{C})·y₃ is a value having the compensated residual frequency offset and channel variation provided by the multiplier 455, exp(−j·Δω_{D})·y₁ is a value having the compensated residual frequency offset and channel variation provided by the multiplier 425, exp(−j·Δω_{E})·y₂ is a value having the compensated residual frequency offset and channel variation provided by the multiplier 445, and exp(−j·Δω_{F})·y₃ is a value having the compensated residual frequency offset and channel variation provided by the multiplier 465.

The parameter δω_{TX} indicates a frequency offset unbalance between two transmission ends. The frequency offset unbalance between two transmission ends is identical to a sub carrier frequency unbalance between two transmission ends. The frequency offset unbalance between two transmission ends may occur when different clock sources or different VCOs are used.

The frequency offset unbalance between two transmission ends is equally applied to every reception end as follows:
δω_{TX}=Δω_{A}−Δω_{D}=Δω_{B}−Δω_{E}=Δω_{C}−Δω_{F} (10)

If δω_{TX} is very small, the (\tilde{H}*\tilde{H})⁻¹ function of Equation 9 uses the function (H*H)⁻¹ of Equation 6 as it is. Therefore, a value calculated in a channel estimation section is applied to a MIMO detection process without calculating (\tilde{H}*\tilde{H})⁻¹ every data symbol section.

Also, δω_{TX} is very small, a frequency offset of each transmission antenna received in one reception antenna is defined as follows:
Δω_{RX1}≈Δω_{A}≈Δω_{D}, Δω_{RX2}26 Δω_{B}≈Δω_{E}, Δω_{RX3}≈Δω_{C}≈Δω_{F} (11)

An arithmetic function used in the MIMO detector 235 is as follows:

$$\begin{matrix}{\tilde{H}}^{*} y = [ \begin{matrix}exp ( - j \cdot {Δω}_{RX 1} ) \cdot {A}^{*} \cdot {y}_{1} + exp ( - j \cdot {Δω}_{RX 2} ) \cdot {B}^{*} \cdot \\ {y}_{2} + exp ( - j \cdot {Δω}_{RX 3} ) \cdot {C}^{*} \cdot {y}_{3} \\ exp ( - j \cdot {Δω}_{RX 1} ) \cdot {D}^{*} \cdot {y}_{1} + exp ( - j \cdot {Δω}_{RX 2} ) \cdot {E}^{*} \cdot \\ {y}_{2} + exp ( - j \cdot {Δω}_{RX 3} ) \cdot {F}^{*} \cdot {y}_{3}\end{matrix} ] \\ = {H}^{*} \cdot [ \begin{matrix}exp ( - j \cdot {Δω}_{RX 1} ) \cdot {y}_{1} \\ exp ( - j \cdot {Δω}_{RX 2} ) \cdot {y}_{2} \\ exp ( - j \cdot {Δω}_{RX 3} ) \cdot {y}_{3}\end{matrix} ]\end{matrix} \qquad ( 12 )$$

The matrix of Equation 12 is applied to FIG. 5. exp(−jΔω_{RX1})·y₁ is a value provided by the multiplier 515, exp(−jΔω_{RX2})·y₂ is a value provided by the multiplier 525, and exp(−jΔω_{RX3})·y₃ is a value provided by the multiplier 535.

A case where the frequency offsets of transmission ends are different to each other and frequency offsets of reception ends are identical to each other, i.e., Δω_{RX1}=Δω_{RX2}=Δω_{RX3}, is illustrated in FIG. 6. A case where frequency offsets of transmission ends are identical to each other and frequency offsets of reception ends are identical to each other is illustrated in FIG. 7.

When the MIMO detector 235 uses the MMSE and additional noise is relatively small by adding an additional noise power term to an inverse matrix term of Equation 5, a noise function is regarded to be approximate to the ZF.

The first and second demappers 240_1 and 240_2 convert the transmission signals detected by the MIMO detector 235 into a bit stream. The transmission signal detected by the MIMO detector 235 is a complex number Quadrature Amplitude Modulation (QAM) signal.

The FEC decoder 250 performs FEC using the bit stream converted by the first and second demappers 240_1 and 240_2 and obtains final bit information.

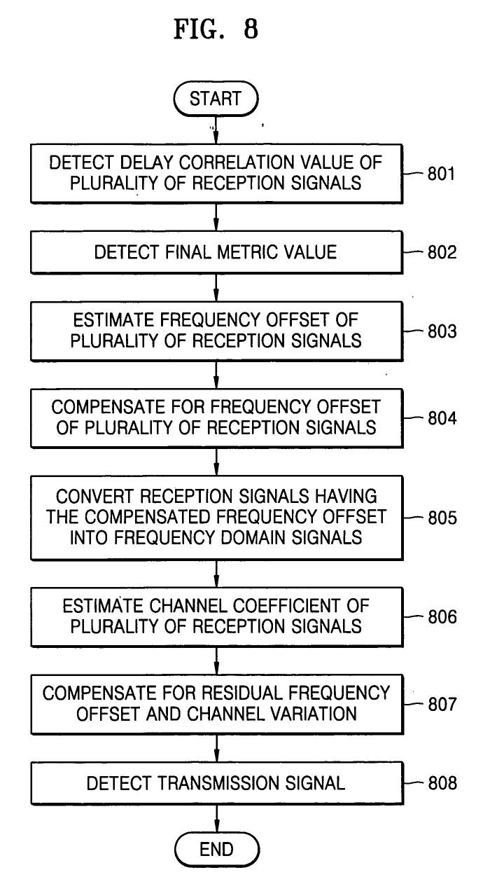

FIG. 8 is a flowchart of a method of compensating for a frequency offset and a channel variation according to an exemplary embodiment of the present invention. The method is applied to a receiver having a plurality of reception ends that receives a transmission signal including pilot signals crossing each other transmitted from a plurality of transmission ends.

Delay correlation values of a plurality of reception signals are detected (Operation 801). A final metric value based on the delay correlation values of the plurality of reception signals is detected (Operation 802). A frequency offset of the plurality of reception signals based on the final metric value is estimated as described in FIG. 2 (Operation 803).

A frequency offset of the plurality of reception signals is compensated based on the estimated frequency offset as described in FIG. 2 (Operation 804) and the reception signals having the compensated frequency offset are converted into frequency domain signals (Operation 805).

Channel coefficients of the plurality of reception signals converted into the frequency domain signals are estimated by sub carriers (Operation 806). A residual frequency offset and a channel variation of the plurality of reception signals are compensated based on the estimated channel coefficients and pilot signals (Operation 807). The residual frequency offset and channel variation of the plurality of reception signals are compensated using a method determined based on identity of frequency offsets between reception ends and transmission ends as described in FIGS. 4 through 7.

Vectors of reception signals transmitted from the plurality of transmission ends are detected based on the reception signals having the compensated residual frequency offset and channel variation and the channel coefficient (Operation 808).

As described above, the present invention can accurately estimate and compensate for a frequency offset in an MIMO-OFDM system comprising a plurality of transmission ends and a plurality of reception ends and provide an OFDM receiver capable of compensating for a channel variation.

If frequency offsets of the plurality of transmission ends are a little different from or identical to each other, reception signals of the plurality of reception ends are compensated using a representative value, thereby reducing amount of computation.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for compensating for a frequency offset between a plurality of reception signals, the apparatus comprising:
a plurality of delay correlators which detect delay correlation values of the plurality of receptions signals;
a final metric value detector which detects a final metric value based on the delay correlation values of the plurality of receptions signals;
a frequency offset estimator which estimates the frequency offset of the plurality of receptions signals based on the final metric value; and
a compensator which compensates for the frequency offset of the plurality of receptions signals based on the estimated frequency offset.

2. The apparatus of claim 1, wherein the final metric value detector detects an average of the delay correlation values of the plurality of receptions signals as the final metric value.

3. The apparatus of claim 1, wherein the final metric value detector detects a delay correlation value of a reception signal having a greatest power among the plurality of reception signals as the final metric value.

4. The apparatus of claim 3, wherein the frequency offset estimator calculates a phase angle of the final metric value, divides a value obtained by multiplying the calculated phase angle and a sampling period by a repetition period value of a preamble section, and estimates the frequency offset.

5. The apparatus of claim 4, wherein the compensator comprises:
an oscillator which generates a complex metric signal corresponding to a frequency of the estimated frequency offset; and
a plurality of multipliers which multiply each of the plurality of reception signals by the generated complex metric signal.

6. The apparatus of claim 2, wherein the frequency offset estimator calculates a phase angle of the final metric value, divides a value obtained by multiplying the calculated phase angle and a sampling period by a repetition period value of a preamble section, and estimates the frequency offset.

7. An apparatus for compensating for a frequency offset and a channel variation of a receiver having a plurality of reception ends that receives a transmission signal including pilot signals crossing each other transmitted from a plurality of transmission ends, the apparatus comprising:
a plurality of channel estimators which estimate channel coefficients of reception signals received from the plurality of reception ends by sub carriers; and
a pre-compensator which compensates for a residual frequency offset and a channel variation of the plurality of reception signals based on the estimated channel coefficients and the pilot signals.

8. The apparatus of claim 7, wherein the plurality of channel estimators estimate the channel coefficients using a long preamble symbol of the reception signals.

9. The apparatus of claim 8, wherein the pre-compensator comprises:
a plurality of channel variation rate estimators which estimate a channel variation rate based on the estimated channel coefficients and the pilot signals; and
a plurality of multipliers which multiply the reception signals by the estimated channel variation rate and obtain reception signals having the compensated residual frequency offset and channel variation.

10. The apparatus of claim 9, wherein a number and arrangement of the plurality of channel variation rate estimators and the plurality of multipliers is determined according to correlation between frequency offsets of the plurality of transmission ends and correlation between frequency offsets of the plurality of reception ends.

11. The apparatus of claim 7, wherein the pre-compensator comprises:
a plurality of channel variation rate estimators which estimate a channel variation rate based on the estimated channel coefficients and the pilot signals; and
a plurality of multipliers which multiply the reception signals by the estimated channel variation rate and obtain reception signals having the compensated residual frequency offset and channel variation.

12. A receiver having a plurality of reception ends, the receiver comprising:
a plurality of delay correlators which delay correlation values of a plurality of receptions signals transmitted from the plurality of reception ends;
a final metric value detector which detects a final metric value based on the delay correlation values of the plurality of receptions signals;
a frequency offset estimator which estimates a frequency offset of the plurality of receptions signals based on the final metric value; and
a compensator which compensates for the frequency offset of the plurality of receptions signals based on the estimated frequency offset.

13. A receiver having a plurality of reception ends that receives a transmission signal including pilot signals crossing each other transmitted from a plurality of transmission ends, the receiver comprising:
a plurality of channel estimators which estimate channel coefficients of reception signals received from the plurality of reception ends by sub carriers; and
a pre-compensator which compensates for a residual frequency offset and a channel variation of the plurality of reception signals based on the estimated channel coefficients and the pilot signals.

14. The receiver of claim 13, further comprising a detector which detects signals transmitted from the plurality of transmission ends based on the channel coefficients estimated in the plurality of channel estimators and the reception signals having the residual frequency offset and the channel variation compensated by the pre-compensator.

15. A receiver that receives a transmission signal including pilot signals crossing each other transmitted from a plurality of transmission ends in a plurality of reception ends, the receiver comprising:
a frequency offset compensation unit which estimates the frequency offset of a plurality of receptions signals received via the plurality of reception ends based on a final metric value of the plurality of reception signals, and compensates for the frequency offset of the plurality of receptions signals based on the estimated frequency offset;
a plurality of Fast Fourier Transformers (FFTs) which convert reception signals having the compensated frequency offset into frequency domain reception signals; and
a frequency offset and channel variation compensation unit which estimates channel coefficients of signals output from the plurality of FFTs by sub carriers, compensates for a residual frequency offset and a channel variation of the reception signals from the plurality of FFTs based on the pilot signals and the estimated channel coefficients, and detects signals transmitted from the plurality of transmission ends based on the reception signals having the compensated residual frequency offset and channel variation and the estimated channel coefficients.

16. A method of compensating for a frequency offset of a plurality of reception signals, the method comprising:
detecting delay correlation values of the plurality of receptions signals;
detecting a final metric value based on the delay correlation values of the plurality of receptions signals;
estimating the frequency offset of the plurality of receptions signals based on the final metric value; and
compensating for the frequency offset of the plurality of receptions signals based on the estimated frequency offset.

17. A method of compensating for a frequency offset and a channel variation of a receiver that receives a transmission signal including pilot signals crossing each other transmitted from a plurality of transmission ends in a plurality of reception ends, the method comprising:
estimating channel coefficients of reception signals received from the plurality of reception ends by sub carriers; and
compensating for a residual frequency offset and a channel variation of the plurality of reception signals based on the estimated channel coefficients and the pilot signals.

18. A method of compensating for a frequency offset and a channel variation of a receiver having a plurality of reception ends that receives a transmission signal including pilot signals crossing each other transmitted from a plurality of transmission ends, the method comprising:
detecting delay correlation values of the plurality of receptions signals;
detecting a final metric value based on the delay correlation values of the plurality of receptions signals;
estimating the frequency offset of the plurality of receptions signals based on the final metric value;
compensating for the frequency offset of the plurality of receptions signals based on the estimated frequency offset;
converting reception signals having the compensated frequency offset into frequency domain signals;
estimating channel coefficients of the frequency domain signals by sub carriers;
compensating for a residual frequency offset and a channel variation of the reception signals based on the pilot signals and the estimated channel coefficients; and
detecting signals transmitted from the plurality of transmission ends based on the reception signals having the compensated residual frequency offset and the channel variation and the estimated channel coefficients.
